(19) United States
(12) Patent Application Publication
(10) Pub. No.: US 2024/0420937 A1
(43) Pub. Date: Dec. 19, 2024

(54) GROUNDING DEVICE FOR THIN FILM FORMATION USING PLASMA

(71) Applicant: Applied Materials, Inc., Santa Clara, CA (US)

(72) Inventors: Yu Cheng LIU, Tainan City (TW); Cheng-yuan LIN, Tainan City (TW); Hsiang AN, San Jose, CA (US); Sam S. WANG, Tainan City (TW)

(21) Appl. No.: 18/732,308

(22) Filed: Jun. 3, 2024

Related U.S. Application Data
(60) Provisional application No. 63/508,422, filed on Jun. 15, 2023.

(51) Int. Cl. H01J 37/34; H01J 37/317; H01J 37/32

(52) U.S. Cl. CPC H01J 37/3435; H01J 37/3178; H01J 37/32183

(57) ABSTRACT

Embodiments of the present disclosure provide a radio frequency (RF) return device. One example RF return device generally includes a bracket for coupling to a chamber body, a cover coupled to the bracket, and a contact plate coupled to the cover and configured contact a substrate support. Using the RF return device described herein generally enables a reduction in temperature that the RF return device and its various components are exposed to, increasing the durability and lifetime of the RF return device. In addition, the RF return device disclosed herein may block chemicals (e.g., fluorine (F)) used in the process chamber from attacking components included in the RF return device, thereby providing enhanced protection to the RF return device.

### CROSS-REFERENCE TO RELATED APPLICATION(S)

This application claims the benefit of and priority to U.S. Provisional Application 63/508,422 filed on Jun. 15, 2023, which is assigned to the assignee hereof and hereby expressly incorporated by reference herein in its entirety as if fully set forth below and for all applicable purposes.

### BACKGROUND

### Field

Embodiments described herein generally relate to methods and apparatus for processing substrates. More particularly, embodiments described herein relate to a modulated radio frequency (RF) current return path for a processing chamber.

### Description of the Related Art

Plasma enhanced chemical vapor deposition (PECVD) is generally employed to deposit thin films on substrates, such as semiconductor substrates, solar panel substrates, and liquid crystal display (LCD) and organic light emitting diode (OLED) substrates used in display manufacture. PECVD is generally accomplished by introducing a precursor gas into a vacuum chamber having a substrate disposed on a susceptor or substrate support. The precursor gas is typically directed through a gas distribution plate situated near the top of the vacuum chamber. The precursor gas in the vacuum chamber is energized (e.g., excited) into a plasma by applying RF power to the chamber from one or more RF sources coupled to the chamber. The excited gas reacts to form a thin film of material on a surface of the substrate (or devices formed thereon). The gas distribution plate is generally connected to a RF power source and the susceptor is typically connected to the chamber body providing a RF current return path.

In the manufacture of OLED devices, PECVD process are generally used to form a thin film on a plurality of OLED devices formed on a substrate. The thin film is utilized to encapsulate and/or hermetically seal the devices (known as thin film encapsulation (TFE)). Uniformity is generally desired in these thin films deposited on the OLED devices using PECVD processes. When the thin films are not uniform across the substrate area, the yield may be decreased. It has been found that the non-uniformity is related to plasma density uniformity, which is affected by RF return. Furthermore, particle generation inside process chambers can lead to particles landing on substrates, which can lower process yield. Therefore, equipment added to process chambers should not contribute significantly to particle generation. Additionally, it is desired that the equipment added to process chambers be durable and long-lasting (to delay maintenance and/or replacement).

Accordingly, there is a need in the art for improved RF return schemes for processing systems that mitigate the problems described above.

### SUMMARY

Embodiments of the present disclosure provide a radio frequency (RF) return device. The RF return device generally includes a bracket for coupling to a chamber body, a cover coupled to the bracket, and a contact plate coupled to the cover and configured to contact a substrate support.

Embodiments of the present disclosure provide a RF return device. The RF return device generally includes a bracket for coupling to a chamber body, a cover coupled to the bracket, where the cover comprises an upper cover and a bottom cover, a spring, where the cover is configured to shelter the spring from a processing volume of the chamber body, and a contact plate coupled to the cover and configured to contact a substrate support, and where the spring is configured to move the contact plate and the bottom cover upwards to a first position when an upward pressure on the contact plate is applied.

Embodiments of the present disclosure provide a process chamber. The process chamber generally includes a chamber body, a substrate support disposed in the chamber body and movable from a first position to a second position, and a RF return device. The RF return device generally includes a bracket for coupling to the chamber body, a cover coupled to the bracket, and a contact plate coupled to the cover and configured to contact the substrate support.

### BRIEF DESCRIPTION OF THE DRAWINGS

So that the manner in which the above recited features of the disclosure can be understood in detail, a more particular description as described herein, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross-sectional view of one embodiment of a plasma processing system when a substrate support is at a first position, according to one or more of the embodiments described herein.

FIG. 1B is a schematic cross-sectional view of the plasma processing system of FIG. 1A when a substrate support is at a second position, according to one or more of the embodiments described herein.

FIG. 2 is a schematic cross-sectional view of a radio frequency (RF) return device, according to one or more of the embodiments described herein.

FIG. 3A is a schematic cross-sectional view of the RF return device of FIG. 2, which is configured to be attached to the chamber body of FIGS. 1A and 1B when a substrate support is at a first position, according to one or more of the embodiments described herein.

FIG. 3B is a schematic cross-sectional view of the RF return device of FIG. 2, which is configured to be attached to the chamber body of FIGS. 1A and 1B when a substrate support is at a second position, according to one or more of the embodiments described herein.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the present disclosure generally relate to a method and apparatus for processing substrates using plasma and/or cleaning components using plasma. More specifically, embodiments provided herein generally relate to a radio frequency (RF) return device configured to provide a grounding path between a substrate support or a susceptor of a process chamber and the process chamber. For example, the RF return device may be configured to be mounted on a sidewall of the process chamber, instead of on the susceptor or substrate support, to provide the grounding path. The process chamber may be a plasma enhanced chemical vapor deposition (PECVD) chamber, a physical vapor deposition (PVD) chamber, an etching chamber, a semiconductor processing chamber, a solar cell processing chamber, an organic light emitting display (OLED) processing chamber, or the like.

The use of an RF return device in accordance with embodiments and techniques of the present disclosure may enable a reduction in the temperature that the RF return device and its various components are exposed to, which may increase the durability and lifetime of the RF return device. In addition, the RF return device disclosed herein may block chemicals (e.g., fluorine (F)) used in the process chamber from attacking components included in the RF return device, thereby providing enhanced protection to the RF return device.

### Processing System

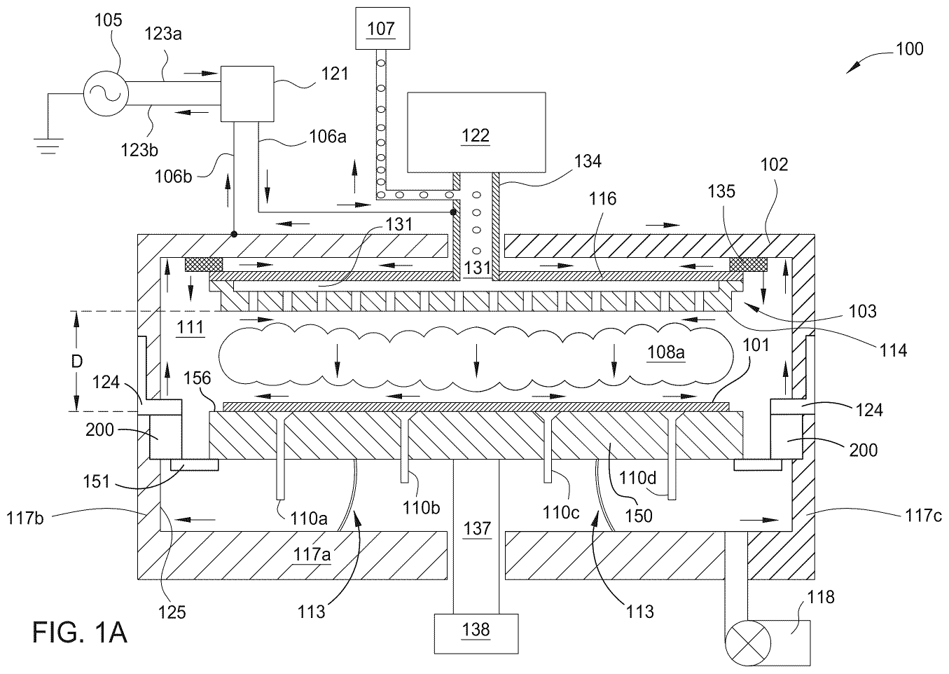

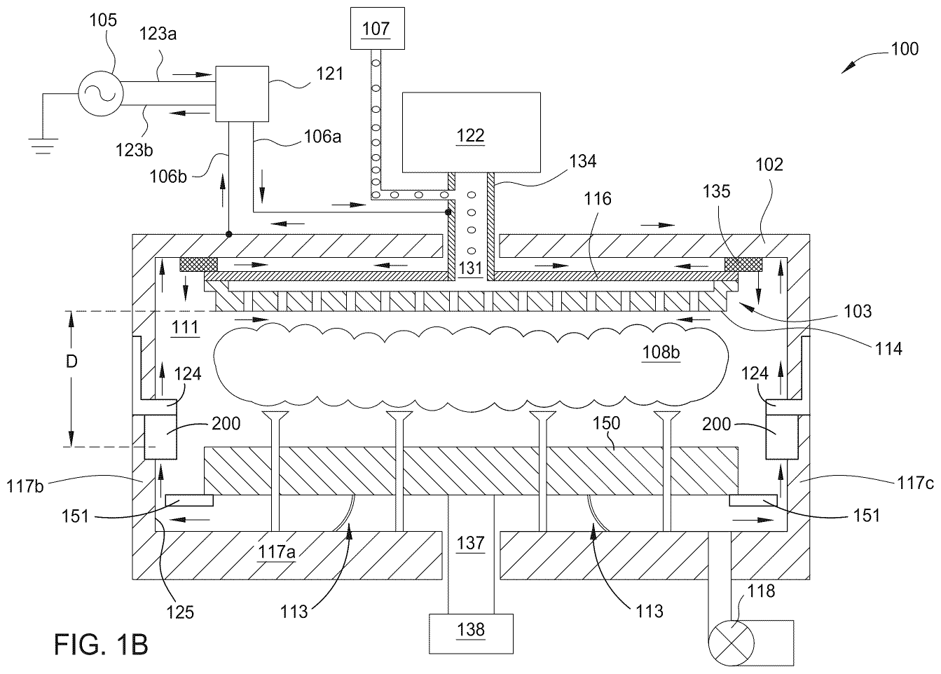

FIG. 1A is a schematic cross-sectional view of one embodiment of a plasma processing system 100 when a substrate support 150 is at a first position (e.g., a processing position), according to one or more of the embodiments described herein. The plasma processing system 100 may be configured to process a substrate 101 using plasma in forming structures and devices on the substrate 101 for use in the fabrication of liquid crystal displays (LCDs), flat panel displays, OLED devices, or photovoltaic cells for solar cell arrays. The substrate 101 may be a thin sheet of metal, plastic, organic material, silicon, glass, quartz, or polymer, among others suitable materials.

The plasma processing system 100 may be configured to deposit a variety of materials on the substrate 101, including dielectric materials (e.g., silicon dioxide (SiO₂), silicon oxynitride (SiOₓN_{y}), derivatives thereof, or combinations thereof), semiconductive materials (e.g., silicon (Si) and dopants thereof), or barrier materials (e.g., Silicon nitride (SiNₓ), SiOₓN_{y} or derivatives thereof). The plasma processing system 100 may also be configured to receive gases such as argon, hydrogen, nitrogen, helium, or combinations thereof, for use as a purge gas or a carrier gas (e.g., Ar, H₂, N₂, He, derivatives thereof, or combinations thereof).

As shown in FIG. 1A, the plasma processing system 100 generally includes a chamber body 102 including a chamber bottom 117a and two sidewalls 117b, 117c that at least partially define a processing volume 111. A substrate support 150 (also referred to as a susceptor) is disposed in the processing volume 111. The substrate support 150 is adapted to support the substrate 101 on a top surface 156 of the substrate support 150 during processing. The substrate support 150 is coupled to an actuator 138 by a shaft 137. The actuator 138 is configured to move the substrate support 150 at least vertically to (1) facilitate transfer of the substrate 101 into and out of the chamber body 102 and/or (2) adjust a distance D between the substrate 101 and a showerhead assembly 103. One or more lift pins 110a, 110b, 110c, and 110d may extend through the substrate support 150. The lift pins 110a, 110b, 110c, and 110d are adapted to contact the chamber bottom 117a of the chamber body 102 and support the substrate 101 above the top surface 156 of the substrate support 150 when the substrate support 150 is lowered by the actuator 138 in order to facilitate transfer of the substrate 101, for example, using the position of the substrate support 150 as shown in FIG. 1B. In a processing position as shown in FIG. 1A, the lift pins 110a, 110b, 110c, and 110d are adapted to be flush with or slightly below the top surface 156 of the substrate support 150 to allow the substrate 101 to lie flat on the substrate support 150.

In some embodiments, the substrate 101 and the substrate support 150 may have a surface area greater than about 5 square meters, such as, for example, about 5.5 square meters. In some embodiments, the substrate 101 and/or the substrate support 150 can be rectangular and can include dimensions of about 2200 mm on a minor side by about 2500 mm on a major side, or greater. In other embodiments, the substrate 101 and the substrate support 150 can be smaller. The structures formed on the substrate 101 may be OLED devices, thin film transistors, or p-n junctions to form diodes for photovoltaic cells.

The showerhead assembly 103 may be configured to supply a processing gas to the processing volume 111 from a processing gas source 122. The plasma processing system 100 also may include an exhaust system 118 configured to apply negative pressure to the processing volume 111. The showerhead assembly 103 may generally be disposed opposing the substrate support 150. For example, the showerhead assembly 103 may be disposed directly above the substrate support 150, in a substantially parallel relationship.

The showerhead assembly 103 may include a gas distribution plate 114 and a backing plate 116. The backing plate 116 may function as a blocker plate to enable formation of a gas volume 131 between the gas distribution plate 114 and the backing plate 116. The processing gas source 122 is connected to the gas distribution plate 114 by a conduit 134. In some embodiments, a remote plasma source 107 may be coupled to the conduit 134 for supplying a plasma of activated gas through the gas distribution plate 114 to the processing volume 111. The plasma from the remote plasma source 107 may include activated gases (e.g., fluorine (F)) for cleaning chamber components disposed in the processing volume 111.

The gas distribution plate 114, the backing plate 116, and the conduit 134 may generally be formed from electrically conductive materials and may be in electrical communication with one another. The chamber body 102 is also formed from an electrically conductive material. The chamber body 102 may generally be electrically insulated from the showerhead assembly 103. In some embodiments, the showerhead assembly 103 can be suspended below a top of the chamber body 102 by attaching the showerhead assembly 103 to an insulator 135 that electrically separates the showerhead assembly 103 from the chamber body 102.

In some embodiments, the substrate support 150 may be electrically conductive. The substrate support 150 and the showerhead assembly 103 may be configured as opposing electrodes for generating a plasma 108a between the substrate support 150 and the showerhead assembly 103 during processing and/or a pre-treatment or post-treatment process. Additionally, the substrate support 150 and the showerhead assembly 103 may also be utilized to support a plasma 108b (FIG. 1B) of cleaning gases during a cleaning process.

The plasma processing system 100 can include a RF power source 105 that can be used to generate the plasma 108a between the showerhead assembly 103 and the substrate support 150 before, during, and after processing. The RF power source 105 may also be used to maintain energized species or further excite cleaning gases supplied from the remote plasma source 107. The RF power source 105 can be coupled to the showerhead assembly 103 to supply RF power for generating the plasma 108a. The RF power source 105 can also be connected to the chamber body 102 to allow for a return path for RF power. The RF power source 105 can make these corresponding connections to the showerhead assembly 103 and to the chamber body through an impedance matching circuit 121.

The plasma processing system 100 includes at least one RF return device 200. In some embodiments, the plasma processing system 100 further includes a plurality of electrical connectors 113. The RF return device 200 may be for coupling between the substrate support 150 and the chamber body 102, which can be used as the ground connection for the RF power source 105. Although two RF return devices 200 are illustrated in FIGS. 1A and 1B, it is contemplated that the plasma processing system 100 may include any number of RF return devices 200. The RF return device 200 may also be referred to as a side grounding device, and/or a bottom grounding device.

As described in further detail below, the RF return device 200 may be electrically conductive and may be configured to be mechanically and/or electrically coupled to the substrate support 150 during certain operations performed in the plasma processing system 100. For example, the RF return device 200 may be configured to selectively contact and/or provide a ground path between the substrate support 150 and the sidewalls 117b, 117c of the grounded chamber body 102, as illustrated in FIG. 1A. In another example, the RF return device 200 may be configured to provide a return path between the substrate support 150 and the chamber bottom 117a of the grounded chamber body 102. In some cases, when the substrate support 150 is raised to the position shown in FIG. 1A, the RF return device 200 is in contact (e.g., electrical contact) with the substrate support 150, and provides a ground connection for the RF power source 105. In other cases, when the substrate support 150 moves to the position shown in FIG. 1B, the RF return device 200 is no longer contact the substrate support 150, and thus does not serve as a ground connection for the RF power source 105. In some embodiments, the RF return device 200 may be configured to electrically contact the substrate support through an extension of the substrate support contact (e.g., electrically contact) the substrate support 150 through an extension 151, as illustrated in FIG. 1A.

The plasma processing system 100 may further include a shadow frame support 124 that extends inwardly into the processing volume 111 from the sidewalls 117b, 117c of chamber body 102. The shadow frame support 124 may be configured to support a shadow frame (not illustrated) that may be used during various operations performed in the plasma processing system 100. For example, a shadow frame may be used to protect portions of the substrate support 150 that remain exposed when supporting a substrate 101 during processing of the substrate 101.

An example RF current path during substrate 101 processing is schematically illustrated by arrows in FIG. 1A. The RF current generally travels from a first lead 123a of the RF power source 105 to a first output 106a of the impedance matching circuit 121, then travels along an outer surface of the conduit 134 to a back surface of the backing plate 116, and then to a front surface of the gas distribution plate 114. From the front surface of the gas distribution plate 114, the RF current goes through plasma 108a and reaches a top surface of the substrate 101 or the substrate support 150, then through the RF return device 200 and/or the electrical connectors 113 to an inner surface 125 of the chamber body 102. From the inner surface 125, the RF current returns to the to a second lead 123b of the RF power source 105 after going through a connection 106b to the impedance matching circuit 121.

In some embodiments, the return path of the RF current during processing may be dependent on a spacing between the substrate support 150 and the showerhead assembly 103, which is depicted as a distance D. The spacing of this distance D is controlled by the elevation of the substrate support 150. In one embodiment, the distance D can be between about 200 mils to about 2000 mils during processing, and different distances D can be used for different processes or when cleaning is performed. In one example, the distance D may be between 600 mils and 1200 mils. At the spacing D shown in FIG. 1A, the RF return device 200 and the electrical connectors 113 may both remain electrically coupled to the RF power source 105. In this embodiment, the RF return path taken by the RF current may be based on the electrical properties and positioning of the RF return device 200 and the electrical connectors 113 with some of these properties including resistance, impedance, and/or conductance of the RF return device 200 and the electrical connectors 113.

FIG. 1B is a schematic cross-sectional view of the plasma processing system 100 of FIG. 1A when the substrate support 150 is at a second position (e.g., a cleaning position), according to one or more of the embodiments described herein. In FIG. 1B, the plasma processing system 100 is shown without the substrate 101 to depict a chamber cleaning procedure, and arrows are shown to schematically depict RF current flow. In these embodiments, energized cleaning gases are flowed to the showerhead assembly 103 and the processing volume 111 from the remote plasma source 107 to supply a plasma 108b within the processing volume 111. During chamber cleaning, the substrate support 150 is moved away from the showerhead assembly 103 and RF power from the RF power source 105 may be applied to the processing volume 111 to maintain or further energize the cleaning gas from the remote plasma source 107. In some embodiments, the spacing or distance D of the substrate support 150 relative to the showerhead assembly 103 during chamber cleaning is greater than the spacing or distance D of the substrate support 150 relative to the showerhead assembly 103 during processing (e.g., deposition), for example as shown in FIG. 1A. In some embodiments, the distance D between the substrate support 150 and the showerhead assembly 103 during a cleaning process is between about 200 mils to about 5000 mils, or greater. In FIG. 1B, the substrate support 150 (e.g., and the extension 151) is located at a distance from the RF return device 200, so that the substrate support 150 is electrically disconnected from the chamber body 102.

In some embodiments, the RF return device 200 may be configured to be mounted on the chamber body 102 (e.g., on a sidewall 117b, 117c of the chamber body 102) instead of on the substrate support 150. As a result of being located further away from the substrate support 150, the RF return device 200 and its components may be susceptible to lower temperatures (e.g., 200 degrees celsius instead of the conventional 350 degrees celsius typically seen at the substrate support 150), resulting in a more durable and longer-lasting RF return devices. For example, the yield strength and lifetime of the first strap 260 and the second strap 270 may be increased due to the lower temperature at a sidewall 117b, 117c of the chamber body 102 (e.g., compared to the temperature at the substrate support 150).

### RF Return Device

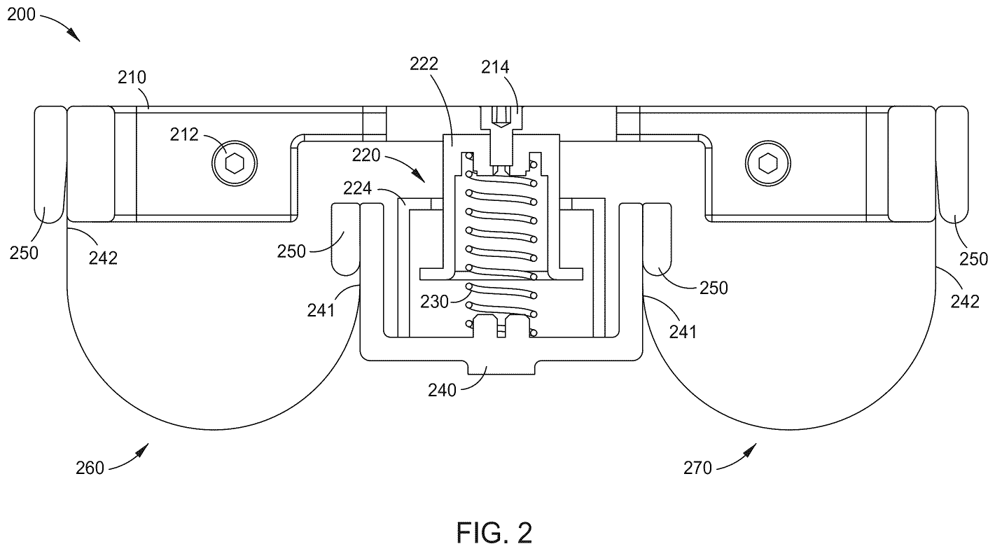

FIG. 2 is a schematic cross-sectional view of a RF return device 200, according to one or more of the embodiments described herein. As described above, the RF return device 200 may be configured to be in electrical contact the substrate support 150 through the extension 151. The RF return device 200 may include a bracket 210, a cover 220, a spring 230, a contact plate 240, a plurality of mounting plates 250, a first strap 260, and a second strap 270, as illustrated in FIG. 2.

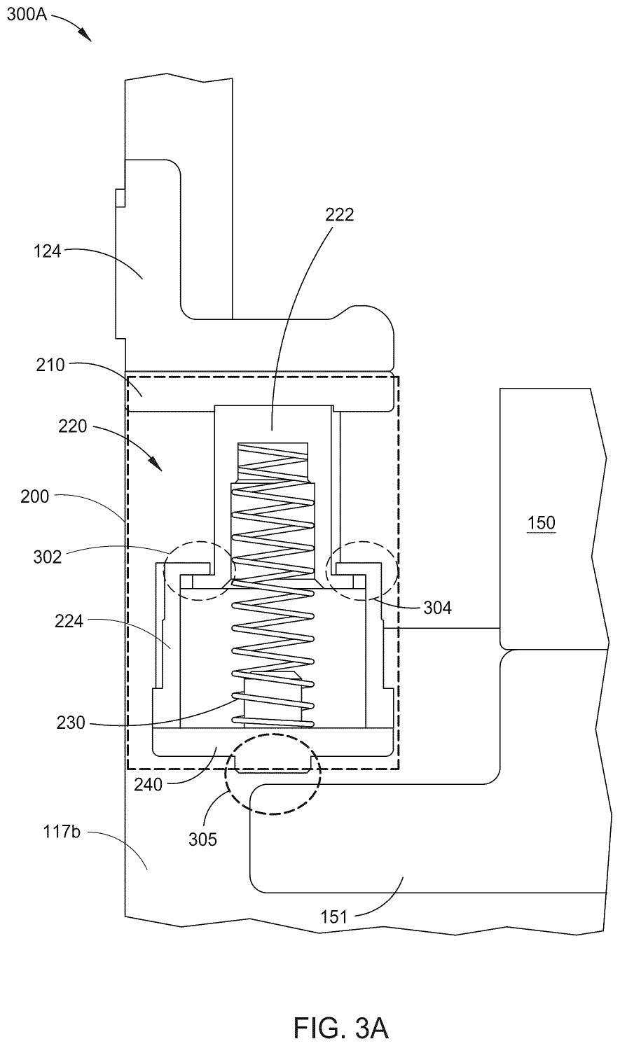

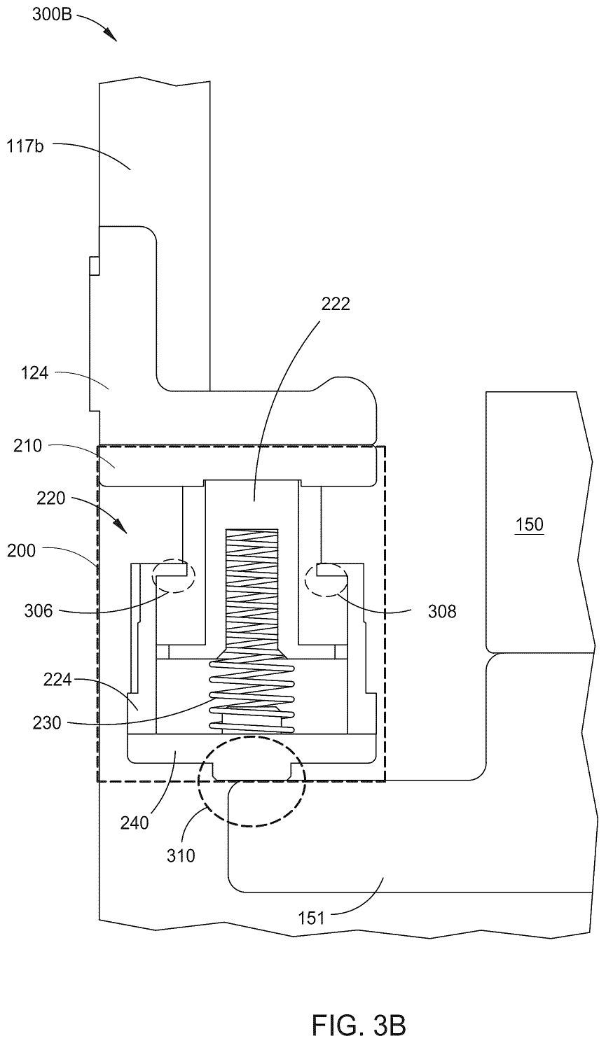

The bracket 210 may be configured to couple the RF return device 200 to the chamber body 102. For example, the bracket 210 may couple the RF return device 200 to a sidewall 117b, 117c of the chamber body 102, as illustrated in FIGS. 1A, 1B, 3A, and 3B. In some cases, the bracket 210 may include one or more fasteners 212 configured to couple the bracket 210 (e.g., and the RF return device 200) to the chamber body 102. The fasteners 212 may be implemented as screws.

In some embodiments, the bracket 210 may include a cover fastener 214 configured to couple the cover 220 of the RF return device 200 to the bracket 210, as illustrated in FIG. 2. The cover fastener 214 may be implemented as a screw. The cover 220 may be substantially concentric in shape, and may include an upper cover 222 and a bottom cover 224. The cover 220 may also be fully concentric in shape. The cover 220 may be self-concentric by the spring 230 inside.

The upper cover 222 may be positioned at the top of the cover 220. As will be described more below, the upper cover 222, the bottom cover 224, and/or the contact plate 240 may house the spring 230. The bottom cover 224, the upper cover 222, and/or the contact plate 240 may be mechanically coupled to the spring 230. The upper cover 222 may be mounted to the RF return device 200, for example, by using the cover fastener 214. The upper cover 222 may be configured to remain stationary when the spring 230 is compressed.

The bottom cover 224 may be positioned at the bottom of the RF return device 200. In some embodiments, the spring 230 may be configured to provide an upward force to the contact plate 240 to ensure the contact plate 240 maintains constant electrical contact with the extension 151 when the substrate support 150 is in the processing position, as illustrated in FIG. 1A. The contact plate 240 and/or the bottom cover 224 may be configured to slide along with the spring 230 when the spring 230 is compressed and decompressed. For example, the spring 230 may be configured to contract (e.g., become compressed) when an upward pressure is applied to the contact plate 240, and the spring 230 may be configured to be relaxed (e.g., become decompressed) when the upward pressure on the contact plate 240 is removed. In some cases, the bottom cover 224 may be mounted to the contact plate 240, for example using fasteners (not shown).

When components inside the RF return device 200, such as the spring 230, are exposed to plasma in the processing volume 111, particles can be generated. These generated particles can then eventually end up at other locations inside the plasma processing system 100 and on the substrate 101 being processed. When these particles end up on the substrate 101, product yield can be lowered. Furthermore, once product yield is lowered from particles escaping from the RF return device 200, it is likely that the RF return device 200 will need to be replaced, which results in significant downtime for the plasma processing system 100. Thus, the cover 220 (e.g., including the upper cover 222 and the bottom cover 224) and/or the contact plate 240 may be configured to at least partially seal (e.g., shelter) the spring 230 and other components in the RF return device 200 from the processing volume 111, which may help reduce the number of particles generated inside the cover 220 by preventing the exposure to plasma of the spring 230 and other components in the RF return device 200. In some cases, the cover 220 and/or the contact plate 240 may function as a barrier that blocks and prevents plasma (e.g., a fluorine (F)-containing plasma) utilized in the processing volume 111 from penetrating inside of the RF return device 200 (e.g., and harming interior components, such as the spring 230), both when the spring 230 is at least partially relaxed (e.g., as shown in FIG. 3A), and when the spring 230 is at least partially compressed (e.g., as shown in FIG. 3B). For example, the plasma processing system 100 may undergo a cleaning process, such as the cleaning process described above with respect to FIG. 1B. Cleaning processes often use highly aggressive radicals (e.g., F radicals), which may generate particles inside the RF return device 200 if the cleaning plasma is able to penetrate the RF return device 200.

The contact plate 240 may be positioned at the bottom of the RF return device 200 and may be coupled to the bottom cover 224, as illustrated in FIG. 2. The contact plate 240 may be formed of a conductor, such as a conductive metal (e.g., aluminum) or a material coated with a metal (e.g., aluminum), or an alloy (e.g., an aluminum-containing alloy). The contact plate 240 may be used to form the electrical connection between a sidewall 117b, 117c of the chamber body 102 and the substrate support 150 through the extension 151 (see e.g., FIG. 1A). Because the extension 151 is electrically connected to a sidewall 117b, 117c of the chamber body 102, this contact between the contact plate 240 and the extension 151 allows RF current from the RF power source 105 to flow between the substrate support 150 and a sidewall 117b, 117c of the chamber body 102, which may be connected to an electrical ground for the RF power source 105.

The plurality of mounting plates 250 may be configured to couple each of the first strap 260 and the second strap 270 to the bracket 210 and the contact plate 240. For example, the first strap 260 may be mounted (e.g., fastened) to the bracket 210 and the contact plate 240 using the mounting plates 250 and fasteners (not shown), as illustrated in FIG. 2. In this example, the second strap 270 may also be mounted (e.g., fastened) to the bracket 210 and the contact plate 240 using the mounting plates 250 and fasteners (not shown), also as illustrated in FIG. 2. The first strap 260 and the second strap 270 may also be referred to as ground straps because the first strap 260 and the second strap 270 may serve as a ground connection for the RF power provided by the RF power source 105. For example, the first strap 260 and the second strap 270 may be used to provide the electrical connection between the substrate support 150 and the chamber body 102. In this example, the RF return path taken by the RF current of the RF power source 105 may travel from the substrate support 150, through the extension 151, the contact plate 240, the first strap 260 and the second strap 270, the bracket 210, and to a sidewall 117b, 117c of the chamber body, as illustrated in FIGS. 3A and 3B.

Each of the first strap 260 and the second strap 270 may include a first section 241 and a second section 242. The first section 241 can move relative to the second section 242 during processes performed in the plasma processing system 100. For example, as the substrate support 150 is raised and the extension 151 is pressed against the contact plate 240 (see FIGS. 1A and 3A), the first section 241 moves upward relative to the second section 242 because the compression of the spring 230 causes the contact plate 240 to be raised. Similarly, when the substrate support 150 is lowered from the position in FIG. 1A to the position in FIGS. 1B, the pressure of the extension 151 against the contact plate 240 is lowered until the extension 151 no longer contacts the contact plate 240, resulting in the first section 241 moving downwards relative to the second section 242.

In some embodiments, the first strap 260 and the second strap 270 can be formed of a conductor, such as a conductive metal (e.g., aluminum) or a material coated with a metal (e.g., aluminum), or an alloy (e.g., an aluminum-containing alloy). In some embodiments, the first strap 260 and the second strap 270 may be implemented as J-type straps. One or more of the components of the RF return device 200 may have an anodized surface. The anodized surface may include anodized aluminum. The bracket 210, the cover 220 (e.g., the upper cover 222 and/or the bottom cover 224), the fasteners 212, the cover fasteners 214, and/or the spring 230 of the RF return device 200 may have the anodized surface.

In some embodiments, an anodizing process may be applied to one or more of the components of the RF return device 200. Applying the anodizing process to components of the RF return device 200 may increase the resistance of the components to corrosion and wear. For example, anodization may be applied to the bracket 210, the cover 220 (e.g., the upper cover 222 and/or the bottom cover 224), the fasteners 212, the cover fasteners 214, and/or the spring 230 of the RF return device 200. The anodization may include chromic acid anodizing, such as anodization MIL-A-8625.

FIG. 3A is a schematic cross-sectional view 300A of the RF return device 200 of FIG. 2, which is configured to be attached to the chamber body 102 of FIGS. 1A and 1B when the substrate support 150 is at the second position (e.g., a cleaning position, as illustrated in FIG. 1B), according to one or more of the embodiments described herein. In FIG. 3A, the spring 230 of the RF return device 200 is illustrated as being in a relaxed state (e.g., decompressed). When in the relaxed state, a bottom portion of the upper cover 222 is in contact with an upper portion of the bottom cover 224, as illustrated in regions 302, 304. As described above with respect to FIG. 1B, the contact plate 240 (and the RF return device 200) may be moved away from the substrate support 150 during a cleaning process, and the RF return device 200 may be electrically disconnected from the substrate support 150. This electrical separation may cause the returning RF current to flow solely through the electrical connectors 113 (when the electrical connectors 113 are present). When the substrate support 150 moves downward from the processing position of FIG. 1A, the contact plate 240 moves away from the extension 151, for example, to the cleaning position in FIG. 1B. As a result, a gap 305 is created between the contact plate 240 and the extension 151, as illustrated in FIG. 3A. This movement of the contact plate 240 away from the extension 151 also results in a removal of the upward force on the contact plate 240 and/or the bottom cover 224, which results in a relaxation and extension of the spring 230 to the position shown in FIG. 3A. The extension of the spring 230 results in a corresponding lowering of the bottom cover 224 and the contact plate 240 to the positions shown in FIG. 3A. In these cases, the lack of an electrical connection between the contact plate 240 and the substrate support 150 may cause the returning RF current to flow only through the electrical connectors 113 (if the electrical connectors 113 are present).

FIG. 3B is a schematic cross-sectional view 300B of the RF return device 200 of FIG. 2, which is configured to be attached to the chamber body 102 of FIGS. 1A and 1B when the substrate support 150 is at the first position (e.g., a processing position as illustrated in FIG. 1A), according to one or more of the embodiments described herein. In some embodiments, the position of the substrate support 150 during processing may be different, and may be depend on desired process spacing and other process criteria. In FIG. 3B, the spring 230 of the RF return device 200 is illustrated as being contracted (e.g., compressed). When in the compressed state, the upper cover 222 may not contact the bottom cover 224, as illustrated in regions 306, 308 of FIG. 3B. In other words, there may be a gap between a lower portion of the upper cover 222 and an upper portion of the bottom cover 224. As described above, when the substrate support 150 is in the processing position, the contact plate 240 (and the RF return device 200) may be located adjacent to the substrate support 150, and the RF return device 200 may be electrically connected to the substrate support 150 (e.g., via extension 151, as shown in region 310). This electrical connection may cause the returning RF current to flow both through the RF return device 200 and through the electrical connectors 113 (if the electrical connectors 113 are present). In some cases, the spring 230 may also be compressed to intermediate positions when the substrate support 150 is at a position lower than the processing position of FIG. 1A, but still in a position at which the contact plate 240 contacts the extension 151 with at least some pressure. In these cases, the electrical connection between the contact plate 240 and the substrate support 150 may still cause the returning RF current to flow both through the RF return device and through the electrical connectors 113.

As described above, the spring 230 may be mechanically coupled to the upper cover 222 and/or the contact plate 240. This mechanical coupling enables an upward force on the contact plate 240 (e.g., resulting from contact with the extension 151) to cause a compression of the spring 230, which forces the contact plate 240 and the bottom cover 224 to slide upwards towards the upper cover 222. For example, when the substrate support 150 moves upward to the processing position in FIG. 1A, the contact plate 240 contacts the extension 151, resulting in an upward force on the contact plate 240 and the bottom cover 224 and a corresponding compression of the spring 230, as shown in FIG. 3B.

In summation, the embodiments described herein provide a RF return device 200 configured to be configured to be mounted on the chamber body 102 (e.g., on a sidewall 117b, 117c of the chamber body 102), and provide a grounding path between a substrate support 150 of a process chamber and the process chamber. As a result of being located away from the substrate support 150, the RF return device 200 and its components may be susceptible to lower temperatures (e.g., 200 degrees celsius instead of the conventional 350 degrees celsius typically seen at the substrate support 150), resulting in more durable and longer-lasting RF return devices. For example, the yield strength and lifetime of the first strap 260 and the second strap 270 may be increased due to the lower temperature at a sidewall 117b, 117c of the chamber body 102. In addition, the RF return device 200 disclosed herein may be configured to block chemicals (e.g., F) used in the chamber body 102 from attacking components included in the RF return device 200, as well as preventing particle generation, thereby providing enhanced protection to the RF return device 200. For example, the cover 220 may be self-concentric, and may be configured to shelter the spring 230 of the RF return device, improving durability and the lifetime of the spring 230.

While the foregoing is directed to embodiments of the present disclosure, other and further embodiments of the disclosure may be devised without departing from the basic scope thereof, and the scope thereof is determined by the claims that follow.

What is claimed is:

1. A radio frequency (RF) return device, comprising:
a bracket for coupling to a chamber body;
a cover coupled to the bracket; and
a contact plate coupled to the cover and configured to contact a substrate support.

2. The RF return device of claim 1, further comprising a spring, wherein the cover is configured to shelter the spring from a processing volume of the chamber body, and wherein the cover is substantially concentric.

3. The RF return device of claim 2, wherein the cover comprises an upper cover and a bottom cover, and wherein the spring is configured to move the contact plate and the bottom cover upwards to a first position when an upward pressure on the contact plate is applied.

4. The RF return device of claim 3, wherein when the contact plate moves upward to the first position, a gap between a portion of the upper cover and a portion of the bottom cover is increased.

5. The RF return device of claim 1, further comprising a first strap including a first section and second section, wherein the first section is for coupling to the contact plate and the second section is coupled to the bracket.

6. The RF return device of claim 1, wherein the contact plate is in electrical contact with the substrate support when the substrate support is in a first position, and wherein the contact plate is not in electrical contact with the substrate support when the substrate support is in a second position.

7. The RF return device of claim 6, wherein the contact plate is configured to electrically contact the substrate support through an extension of the substrate support.

8. The RF return device of claim 1, wherein the bracket is for coupling to a sidewall of the chamber body.

9. The RF return device of claim 1, wherein the contact plate comprises a conductive material, and wherein the conductive material comprises an aluminum-containing alloy.

10. The RF return device of claim 1, wherein at least one of the bracket or the cover comprise an anodized surface.

11. A radio frequency (RF) return device, comprising:
a bracket for coupling to a chamber body;
a cover coupled to the bracket, wherein the cover comprises an upper cover and a bottom cover;
a spring, wherein the cover is configured to shelter the spring from a processing volume of the chamber body; and
a contact plate coupled to the cover and configured to contact a substrate support, wherein the spring is configured to move the contact plate and the bottom cover upwards to a first position when an upward pressure on the contact plate is applied.

12. A process chamber, comprising
a chamber body;
a substrate support disposed in the chamber body, the substrate support being movable from a first position to a second position; and
a RF return device, wherein the RF return device comprises:
a bracket for coupling to the chamber body;
a cover coupled to the bracket; and
a contact plate coupled to the cover and configured to contact the substrate support.

13. The process chamber of claim 12, wherein the RF return device further comprises a spring, wherein the cover is configured to shelter the spring from a processing volume of the chamber body, and wherein the cover is substantially concentric.

14. The process chamber of claim 13, wherein the cover comprises an upper cover and a bottom cover, and wherein the spring is configured to move the contact plate and the bottom cover upwards to a first position when an upward pressure on the contact plate is applied.

15. The process chamber of claim 14, wherein when the contact plate moves upward to the first position, a gap between the upper cover and the bottom cover is increased.

16. The process chamber of claim 12, wherein the RF return device further comprises a first strap including a first section and second section, wherein the first section is for coupling to the contact plate and the second section is coupled to the bracket.

17. The process chamber of claim 12, wherein the contact plate is in electrical contact with the substrate support when the substrate support is in the first position, and wherein the contact plate is not in electrical contact with the substrate support when the substrate support is in the second position.

18. The process chamber of claim 17, wherein the contact plate is configured to electrically contact the substrate support through an extension of the substrate support.

19. The process chamber of claim 12, wherein the bracket is for coupling to a sidewall of the chamber body.

20. The process chamber of claim 12, wherein the contact plate comprises a conductive material, and wherein the conductive material comprises an aluminum-containing alloy.
